(19) United States
(12) Patent Application Publication
(10) Pub. No.: US 2003/0076863 A1
(43) Pub. Date: Apr. 24, 2003

(54) Laser bar and method associated therewith

(76) Inventor: Thomas Zelenka, Monkeberg (DE)

Correspondence Address: LERNER AND GREENBERG, P.A., Post Office Box 2480, Hollywood, FL, 33022-2480, US

(21) Appl. No.: 09/811,802

(22) Filed: Mar. 19, 2001

(30) Foreign Application Priority Data
Mar. 17, 2000 (DE) 100 13 265.0

(51) Int. Cl. H01S 5/00

(52) U.S. Cl. 372/43

(57) ABSTRACT

A method for prolonging the service life and increasing manufacturing output, respectively, of solid-state lasers provided and predetermined, respectively, for continuous operation, which includes forming the lasers into a laser bar with a group of active laser strips arranged next to one another at a mutually spaced distance, activating the active laser strips during the continuous operation by having current applied jointly thereto, and providing the laser bar with at least one group of further laser strips, respectively, arranged in interspaces between respective adjacent active laser strips of the group thereof. While the current is applied to the active laser strips, the method further includes applying no current to the further laser strips so that the further laser strips are inactive, and checking the functionality of the active laser strips during the continuous operation, and activating at least one of the inactive laser strips if a failure of at least one of the active laser strips should occur. The invention also includes a laser bar and a solid-state laser including the laser bar.

### BACKGROUND OF THE INVENTION

### FIELD OF THE INVENTION

The invention relates to the art of solid-state lasers, in particular to pumping high-power solid-state lasers and direct material processing by laser diode arrays which include a plurality of strip-type laser emitters in the form of laser diodes (laser strips) which are arranged adjacent to one another. These laser diode arrays are often referred to as laser bars.

Laser bars may be made up of individual separate laser diodes or monolithically produced from a continuous strip of semiconductor material, e.g., GaAs, which is subdivided into individual integrated laser diodes during production. Current is applied jointly to all the laser diodes of a laser bar, so that they emit their laser radiation jointly. In addition to the laser radiation, however, considerable quantities of heat are generated, the dissipation of which poses ever increasing problems the closer the laser diodes are arranged adjacent to one another. If the laser diodes are spaced a short distance from one another, it is necessary to operate in a pulsed mode, i.e., to supply current only very briefly to the laser diodes.

For solid-state lasers which are supposed to operate continuously and to emit laser radiation without interruption, a sufficiently great spaced distance between adjacent laser diodes of the laser bar is necessary, namely about 100 μm for a given width of the laser diodes of 50 μm, so that the utilization factor of the laser diode arrays is only about 30% for thermal reasons. Even this relatively low utilization factor is possible only if care is taken to ensure that the laser diodes are cooled sufficiently, usually by mounting the laser bar on a heat sink.

The service life of a diode-pumped solid-state laser is primarily limited by the service life of the individual laser diodes of the laser bar, because exchanging a failed laser diode is not possible in the case of monolithically produced laser bars and can be effected only in a rather highly complex manner in the case of laser bars formed of combined laser diodes. Because the pumping laser diodes critically affect the costs of the solid-state laser, however, a lengthy service life is of great importance.

Moreover, due to the high costs of the laser bars, the highest possible yield is also desirable during the production thereof. In other words, the number of produced laser bars which are unusable due to one or more defective laser diodes should be as low as possible.

### SUMMARY OF THE INVENTION

It is accordingly an object of the invention to provide laser bars which, by comparatively simple measures, have a prolonged service life, of which the yield of usable laser bars during the manufacture thereof is increased, and/or of which the average laser power is increased.

With the foregoing and other objects in view, there is provided, in accordance with one aspect of the invention, a method for prolonging the service life and increasing manufacturing output, respectively, of solid-state lasers provided and predetermined, respectively, for continuous operation, the lasers forming a laser bar with a group of active laser strips arranged next to one another at a mutually spaced distance, the active laser strips being activated during the continuous operation by having current applied jointly thereto, which comprises, providing the laser bar with at least one group of further laser strips, respectively, arranged in interspaces between respective adjacent active laser strips of the group thereof; while the current is applied to the active laser strips, applying no current to the further laser strips so that the further laser strips are inactive; checking the functionality of the active laser strips during the continuous operation; and activating at least one of the inactive laser strips if a failure of at least one of the active laser strips should occur.

In accordance with another aspect of the invention, there is provided a method for prolonging the service life of solid-state lasers provided for continuous operation, the lasers forming a laser bar with a group of active laser strips arranged next to one another at a mutually spaced distance, the active laser strips being activated during the continuous operation by having current jointly applied thereto, which comprises, providing the laser bar with at least one group of further laser strips, respectively, arranged in interspaces between respective adjacent active laser strips of the group thereof; while the current is applied to the active laser strips, applying no current to the further laser strips so that the further laser strips are inactive; checking the functionality of the active laser strips during the continuous operation; and activating at least one of the inactive laser strips if a failure of at least one of the active laser strips should occur.

In accordance with a further aspect of the invention, there is provided a method for increasing manufacturing output of solid-state lasers predetermined for continuous operation, the lasers forming a laser bar with a group of active laser strips arranged next to one another at a mutually spaced distance, the active laser strips being activated during the continuous operation by having current jointly applied thereto, which comprises, providing the laser bar with at least one group of further laser strips, respectively, arranged in interspaces between respective adjacent active laser strips of the group thereof; while the current is applied to the active laser strips, applying no current to the further laser strips so that the further laser strips are inactive; and after providing the laser bar with the inactive further laser strips, checking the functionality of the active laser strips during the continuous operation, and activating at least one of the inactive laser strips if a defect should occur in at least one of the active strips.

In accordance with an additional mode, the method of the invention includes providing a number n of the active laser strips and a number approximately n of the inactive laser strips, and further includes, in the event of a failure of and a defect in, respectively, at least one laser strip of the group of active laser strips, jointly deactivating all n laser strips of this group and all the laser strips of the group of inactive laser strips.

In accordance with yet another mode, the method of the invention includes providing a number n of the active laser strips and a number approximately 2n of the inactive laser strips, and further includes, in the event of a failure of and a defect in, respectively, at least one laser strip of the group of active laser strips, jointly deactivating all n laser strips of this group and all the inactive laser strips which are arranged directly to one of the lefthand and the righthand side, respectively, of an active laser strip.

In accordance with yet a further mode, the method of the invention includes, in continuous operation, applying current alternately to the groups of laser strips.

In accordance with yet an added mode, the method of the invention includes individually controlling the further laser strips for activating them.

In accordance with yet an additional mode, the method of the invention includes, for adjusting to altered spaced distances between two adjacent laser strips, after activating a further laser strip, altering the operating point of the active laser strip and at least one operating point of adjacent laser strips.

In accordance with an additional aspect of the invention, there is provided a method for increasing laser power of solid-state lasers predetermined for continuous operation, the lasers forming a laser bar with a group of active laser strips arranged next to one another at a mutually spaced distance, the active laser strips being activated during the continuous operation by having current jointly applied thereto, which comprises, providing the laser bar with at least one further group of laser strips which are arranged, respectively, in interspaces between two adjacent laser strips of the first-mentioned group of laser strips, applying current jointly to the laser strips of the further group thereof during the continuous operation, the current being supplied to the groups of laser strips alternately, in a pulsed manner.

In accordance with another mode, the method of the invention includes selecting the pulse duration so that current is always supplied to one of the groups of laser strips.

In accordance with yet another aspect of the invention, there is provided a laser bar with a first group of laser strips disposed adjacent to and at a spaced distance from one another and being connectable to a current source in a parallel circuit, comprising at least one further group of laser strips disposed in interspaces between two adjacent laser strips of the first group and being connectable to the current source separately from the laser strips of the first group.

In accordance with another feature of the invention, the laser strips of the further group are jointly connectable to the current source.

In accordance with a further feature of the invention, the laser strips of each group are connected to one another in a parallel circuit.

In accordance with an added feature of the invention, the laser strips of the further group are individually connectable to the current source.

In accordance with an additional feature of the invention, a respective laser strip of a further group of laser strips is disposed between two adjacent laser strips of the first group of laser strips.

In accordance with yet another feature of the invention, the laser strips of the first group are n in number, and the number of laser strips of each further group is one of n+1, n and n−1.

In accordance with yet a further feature, the spaced distance between two adjacent laser strips of a group exceeds the width of a laser strip.

In accordance with yet an added feature of the invention, the spaced distance between two adjacent laser strips of a group exceeds the width of two laser strips.

In accordance with yet an additional feature of the invention, two laser strips, respectively, of two further groups of laser strips are arranged pairwise between two adjacent laser strips of the first group of laser strips.

In accordance with another feature of the invention, the laser strips of each group, respectively, are arranged at identical spaced distances from one another and from adjacent laser strips.

In accordance with a concomitant aspect of the invention, there is provided a solid-state laser having a laser bar with a first group of laser strips disposed adjacent to and at a spaced distance from one another and being connectable to a current source in a parallel circuit, comprising at least one further group of laser strips disposed in interspaces between two adjacent laser strips of the first group and being connectable to the current source separately from the laser strips of the first group, the solid-state laser also having a switching device for at least individually connecting laser strips of the further group to a current source.

The invention is thus based upon the concept of utilizing the spaced distances between adjacent active laser diodes, distances which are necessary for thermal reasons in the case of laser bars for continuous operation and which exceed the width of the laser diodes, in order to provide one or more further inactive laser diodes, respectively, in the interspaces between the active laser diodes to which current is applied jointly. The inactive laser diodes can either remain inactive and be activated individually or in groups in place of one or more laser diodes which have failed during the operating time or have already been found to be defective during manufacture, in order to replace the failed or defective laser diode or diodes and all the active laser diodes, respectively, and, as a result, to prolong the service life of the laser bar and to increase the manufacturing yield or output, respectively. Alternatively, however, current can also be jointly applied to these laser diodes in groups in an alternating manner with the active laser diodes, in order to achieve an occasional cooling of the laser diodes, without any interruption of the laser emission of the laser bar and, consequently, without additional measures for cooling, achieving an increase in the average laser power of the laser bar.

In principle, it is possible to provide each laser diode of the further group or groups with a dedicated connection, so that they can be activated, i.e., connected up, individually in the event of a defect or failure of an adjacent active laser diode, in order to replace the defective or failed laser diode. However, because this activated laser diode is at different spaced distances from the adjacent active laser diodes of the first group, one of these spaced distances being less than the distance required for the dissipation of heat, it is necessary, at the same time, to alter the operating point of the activated laser diode and/or that of the more closely adjacent laser diode by altering the operating current, in order to take the altered distances into account. Although this results in a given drop in the average laser power, the drop in power turns out to be considerably smaller than in the case of a defect or failure of an entire laser diode.

A drop in the average laser power can be completely prevented, however, if, in accordance with a preferred inventive improvement, an inactive laser diode is, respectively, provided in each of the interspaces between two active laser diodes and also preferably at an end of the row of active laser diodes, with the result that the number of the inactive laser diodes corresponds to the number of active laser diodes and, in the event of a failure or defect of one or more active laser diodes, all of the active laser diodes are deactivated and, in their place, all the inactive laser diodes are activated, i.e., have current applied thereto.

This applies as well to the case wherein two inactive laser diodes, respectively, are provided in each of the interspaces between two active laser diodes and, if appropriate, at an end of the row of active laser diodes, so that the number of the inactive laser diodes is about twice as large as the number of active laser diodes and, in the event of a failure or defect of one or more active laser diodes, all of the active laser diodes are deactivated and, in their place, respectively, one of the two inactive laser diodes in the interspaces or at the end of the row is activated.

In both cases, it is possible, moreover, to supply current alternately to the two and more groups of laser diodes, respectively, by providing for a voltage always to be applied only momentarily to one group of laser diodes, while the other group or groups remain without voltage and current for this period of time. Due to the cooling of the deenergized laser diodes, the temperature of the laser bar can be kept lower, which likewise contributes to prolonging the service life and additionally prevents shifts in the wavelengths of the emitted laser light. The duration of the pulses is chosen so that one group of laser diodes always emits laser radiation.

The greater cooling of the laser diodes during alternating or pulsed operation of the different groups can also be utilized for increasing the average laser power of the laser bar if the switched-on duration of the groups of laser diodes is chosen so that the resulting heat is dissipated to the greatest possible extent in the intervals between two pulses. The optimum pulse duration is best determined by experiments because it depends upon the type of heat sink used, and also upon the width of the laser diodes and the spaced distance therebetween. In the event of failure of one or more laser diodes of a laser bar with two or three groups of laser diodes which operate in alternating operation and are interlinked with one another, the power drop caused thereby cannot, however, be compensated for again.

In order to minimize the circuitry outlay in the manufacture of the solid-state laser, in accordance with a further preferred improvement of the invention, all the laser diodes of a group are fixedly connected to a connection by electrodes on the laser bar in a parallel circuit, while the connections of each group can be connected to a current source once again in a parallel circuit, with the result that a circuit of the solid-state laser is able to manage with a number of switches corresponding to that of the number of groups. As an alternative, however, provision may also be made for connecting only one group of laser diodes in parallel, to which group current is supposed to be applied continuously in continuous operation, while the laser diodes of a further group which are arranged in the interspaces between the laser diodes of the one group are, respectively, connected to a separate connection on the laser bar, so that they can be connected up individually in the event of a failure of or defect in the active laser diodes.

Other features which are considered as characteristic for the invention are set forth in the appended claims.

Although the invention is illustrated and described herein as embodied in a laser bar and method associated therewith, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings, wherein:

### BRIEF DESCRIPTION OF THE DRAWINGS

FIG. 1 is a fragmentary diagrammatic longitudinal plan view of one embodiment of a laser bar constructed in accordance with the invention; and

FIG. 2 is a view like that of FIG. 1 of a different laser bar according to the invention.

### DESCRIPTION OF THE PREFERRED EMBODIMENTS

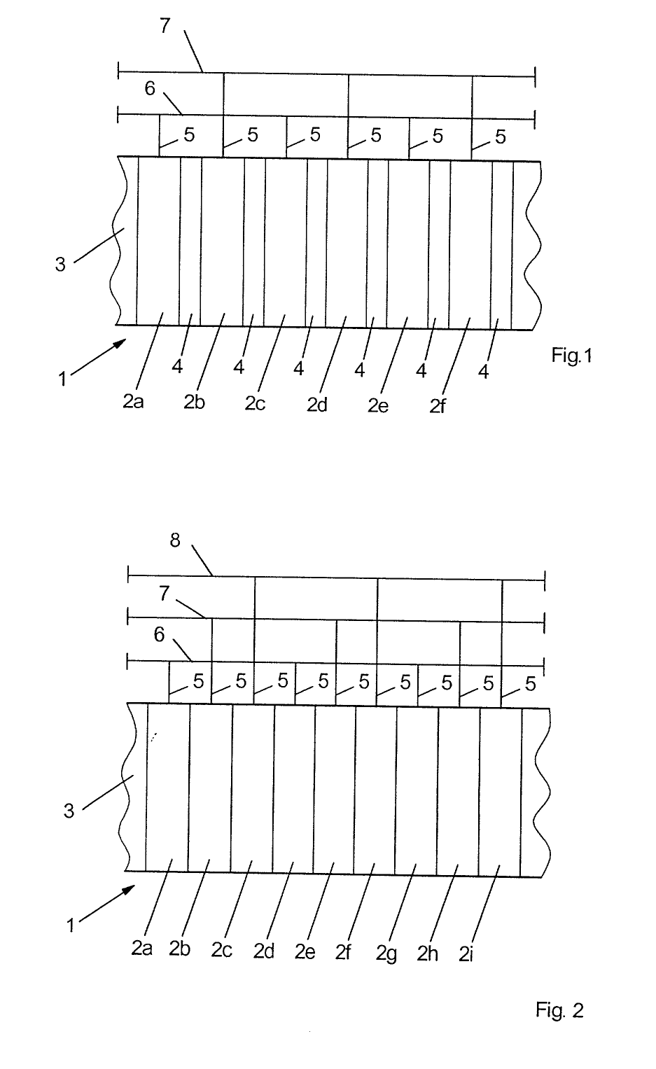

Referring now to the drawing and, first, particularly to FIG. 1 thereof, there is shown therein part of a laser bar 1 which serves as a pumping laser for a continuously operating solid-state laser and primarily includes a plurality of mutually adjacent strip-type laser diodes or laser strips 2a,2b,2c,2d,2e,2f . . . having a width of about 100 μm and being arranged at identical spaced distances of about 5 μm from one another on a substrate 3. The laser strips 2a,2b,2c,2d,2e,2f . . . and the interspaces 4 between the laser strips 2 are produced monolithically from a single semiconductor monocrystal, such as gallium arsenide (GaAs), for example, the semiconductor monocrystal remaining unprocessed, during the production of the laser bar 1, in the interspaces 4 between the laser strips 2a to 2f and so forth.

The laser strips 2a,2b,2c,2d,2e,2f . . . are subdivided into two groups of laser strips, respectively, 2a,2c,2e . . . and 2b,2d,2f . . . , which are connected to one of two electrical current supply lines 6 and 7, respectively, and ground (not illustrated) in a parallel circuit by individual electrodes 5. For a length of the laser bar 1 of about 11 mm, the total number of laser strips is one hundred four, each of the two groups of laser strips 2a,2c,2e . . . and 2b,2d,2f . . . , respectively, including fifty-two laser strips. Apart from the respective outermost laser strips, the laser strips 2a,2c,2e . . . and 2b,2d,2f . . . of the two groups are arranged so that a respective laser strip 2a or 2cor 2e . . . of one group of laser strips 2a,2c,2e . . . is arranged in the center between two adjacent laser strips 2band 2dand 2f . . . , respectively, of the other group of laser strips 2b,2d,2f, and the reverse, and so that the spaced distances between two laser strips of a group are about 100 μm, corresponding to twice the width of a laser strip.

If the laser bar 1 is in continuous operation mode, current is supplied from a non-illustrated current source only to one of the two groups of laser strips, for example, the laser strips 2a,2c,2e . . . , via the associated current supply line 6 and the associated electrodes 5, in order to avoid excessive heating of the laser bar 1. This group of laser strips 2a,2c,2e . . . is designated as the active group.

In this regard, the laser strips of the other group 2b,2d,2f . . . can be used as redundant laser strips in that they remain completely inactive from the beginning of the operating period over a relatively long period of time, while current is continuously applied to the active group 2a,2c,2e . . . over this period of time during the desired switched-on duration period of the laser, with the result that the laser strips of the group 2a,2c,2e . . . emits laser light in continuous operation. Only in the event of a failure of one or more laser strips of the active group 2a,2c,2e . . . is the connection line 6 of the theretofore active group 2a,2c,2e . . . isolated from the current source, while at the same time the current supply line 7 of the theretofore inactive group of laser strips 2b,2d,2f . . . is connected to the current source in order to activate the laser strips 2b,2d,2f . . . of the theretofore inactive group.

The failure of one or more laser strips 2a,2c,2e . . . can be determined, for example, by measuring the resistance of the laser strips 2a,2c,2e . . . during operation.

Due to the changeover or conversion to the theretofore inactive laser strips 2b,2d,2f . . . , it is possible to postpone a costly exchange of the laser bar 1 mounted on an otherwise non-illustrated heat sink until the failure of one or more further laser strips 2b,2d,2f . . . and, as a result, to approximately double the service life of the laser bar 1.

The functionality of the laser strips of the active group can, of course, also be checked directly after manufacture, in which case, in the event of a defect of one or more laser strips of one group 2a,2c,2e . . . , for example, the laser strips of the other group 2b,2d,2f . . . can be connected to the current source. Consequently, during the manufacture of laser bars 1, the yield or output can be increased inasmuch as these laser bars 1 can be used as laser bars which have a conventional service life, for example, for applications with a shorter switched-on duration period.

As an alternative, however, currents can be applied alternately in a pulsating manner to the laser strips of both groups 2a,2c,2e . . . and 2b,2d,2f . . . , the duration of the pulses, respectively, corresponding to the time between two pulses, so that the pumping laser is in continuous operation and continually emits laser light. Moreover, the duration of each pulse is chosen so as to prevent the laser strips from being heated beyond a predetermined or prescribed temperature value. In comparison with a conventional laser bar for continuous operation wherein current is continually applied to all the laser strips jointly, as a result of the cooling of the laser strips between two successive pulses, the operating point of the laser strips can be shifted upwardly, so that the average laser power can be increased.

In the case of the laser bar 1 illustrated in FIG. 2, adjacent laser strips 2a, 2b, 2c, 2d, 2e, 2f, 2g, 2h, 2i . . . , respectively, are directly next to one another and subdivided into three groups of mutually interlinked laser strips 2a, 2d, 2g . . . ; 2b, 2e, 2h . . . ; 2c, 2f, 2i . . . , the total number of which is one hundred three for a corresponding width of the laser strips 2. The first group 2a, 2d, 2g . . . includes thirty-five laser strips, including the two outermost laser strips, while the second and third groups 2b, 2e, 2h . . . ; 2c, 2f, 2i . . . ; respectively, include thirty-four laser strips which are arranged in pairs in the interspaces between the laser strips of the first group 2a, 2d, 2g . . . .

In the case of this laser bar 1, three current supply lines 6,7 and 8 are provided, a respective one for each group of laser strips 2a, 2d, 2g . . . ; 2b, 2e, 2h . . . ; and 2c, 2f, 2i . . . , with the result that they have currents applied thereto successively, in the event of a defect or a failure of individual laser strips, or intermittently for the purpose of increasing the laser power. The service life of the laser bar can be prolonged approximately three-fold by this arrangement.

The number of mutually interlinked groups of laser strips can also be more than three.

I claim:

1. A method for prolonging the service life and increasing manufacturing output, respectively, of solid-state lasers provided and predetermined, respectively, for continuous operation, which comprises forming the lasers into a laser bar with a group of active laser strips arranged next to one another at a mutually spaced distance; activating the active laser strips during the continuous operation by applying current jointly thereto; providing the laser bar with at least one group of further laser strips, respectively, arranged in interspaces between respective adjacent active laser strips of the group thereof; while the current is applied to the active laser strips, applying no current to the further laser strips so that the further laser strips are inactive; checking the functionality of the active laser strips during the continuous operation; and activating at least one of the inactive laser strips if a failure of at least one of the active laser strips should occur.

2. A method for prolonging the service life of solid-state lasers provided for continuous operation, which comprises forming the lasers into a laser bar with a group of active laser strips arranged next to one another at a mutually spaced distance; activating the active laser strips during the continuous operation by applying current jointly thereto; providing the laser bar with at least one group of further laser strips, respectively, arranged in interspaces between respective adjacent active laser strips of the group thereof; while the current is applied to the active laser strips, applying no current to the further laser strips so that the further laser strips are inactive; checking the functionality of the active laser strips during the continuous operation; and activating at least one of the inactive laser strips if a failure of at least one of the active laser strips should occur.

3. A method for increasing manufacturing output of solid-state lasers predetermined for continuous operation; which comprises forming the lasers into a laser bar with a group of active laser strips arranged next to one another at a mutually spaced distance; activating the active laser strips during the continuous operation by applying current jointly thereto; providing the laser bar with at least one group of further laser strips, respectively, arranged in interspaces between respective adjacent active laser strips of the group thereof; while the current is applied to the active laser strips, applying no current to the further laser strips so that the further laser strips are inactive; and after providing the laser bar with the inactive further laser strips, checking the functionality of the active laser strips during the continuous operation, and activating at least one of the inactive laser strips if a defect should occur in at least one of the active strips.

4. The method according to claim 1, which includes providing a number n of the active laser strips and a number approximately n of the inactive laser strips, and further includes, in the event of a failure of and a defect in, respectively, at least one laser strip of the group of active laser strips, jointly deactivating all n laser strips of this group and all the laser strips of the group of inactive laser strips.

5. The method according to claim 1, which includes providing a number n of the active laser strips and a number approximately 2n of the inactive laser strips, and further includes, in the event of a failure of and a defect in, respectively, at least one laser strip of the group of active laser strips, jointly deactivating all n laser strips of this group and all the inactive laser strips which are arranged directly to one of the lefthand and the righthand side, respectively, of an active laser strip.

6. The method according to claim 1, which includes, in continuous operation, applying current alternately to the groups of laser strips.

7. The method according to claim 1, which includes individually controlling the further laser strips for activating them.

8. The method according to claim 7, which includes, for adjusting to altered spaced distances between two adjacent laser strips, after activating a further laser strip, altering the operating point of the active laser strip and at least one operating point of adjacent laser strips.

9. A method for increasing laser power of solid-state lasers predetermined for continuous operation, which comprises, forming the lasers into a laser bar with a group of active laser strips arranged next to one another at a mutually spaced distance; activating the active laser strips during the continuous operation by having current jointly applied thereto; providing the laser bar with at least one further group of laser strips which are arranged, respectively, in interspaces between two adjacent laser strips of the first-mentioned group of laser strips; applying current jointly to the laser strips of the further group thereof during the continuous operation, the current being supplied to the groups of laser strips alternately, in a pulsed manner.

10. The method according to claim 9, which includes selecting the pulse duration so that current is always supplied to one of the groups of laser strips.

11. A laser bar, comprising a first group of laser strips disposed adjacent to and at a spaced distance from one another and being connectable to a current source in a parallel circuit, at least one further group of laser strips disposed in interspaces between two adjacent laser strips of the first group and being connectable to the current source separately from the laser strips of the first group.

12. The laser bar according to claim 11, wherein the laser strips of the further group are jointly connectable to the current source.

13. The laser bar according to claim 11, wherein the laser strips of each group are connected to one another in a parallel circuit.

14. The laser bar according to claim 11, wherein the laser strips of the further group are individually connectable to the current source.

15. The laser bar according to claim 11, wherein a respective laser strip of a further group of laser strips is disposed between two adjacent laser strips of the first group of laser strips.

16. The laser bar according to claim 11, wherein the laser strips of the first group are n in number, and the number of laser strips of each further group is one of n+1, n and n−1.

17. The laser bar according to claim 11, wherein the spaced distance between two adjacent laser strips of a group exceeds the width of a laser strip.

18. The laser bar according to claim 11, wherein the spaced distance between two adjacent laser strips of a group exceeds the width of two laser strips.

19. The laser bar according to claim 18, wherein two laser strips, respectively, of two further groups of laser strips are arranged pairwise between two adjacent laser strips of the first group of laser strips.

20. The laser bar according to claim 11, wherein the laser strips of each group, respectively, are arranged at identical spaced distances from one another and from adjacent laser strips.

21. A solid-state laser having a laser bar according to claim 11, and also having a switching device for at least individually connecting laser strips of the further group to a current source.
